(19) United States
(12) Patent Application Publication
(10) Pub. No.: US 2026/0293196 A1
(43) Pub. Date: Sep. 24, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Kohei OASA, Tokyo (JP); Tatsuya NISHIWAKI, Yokohama Kanagawa (JP); Kentaro ICHINOSEKI, Higashimurayama Tokyo (JP); Keiko KAWAMURA, Yokohama Kanagawa (JP)

(21) Appl. No.: 19/286,038

(22) Filed: Jul. 30, 2025

(30) Foreign Application Priority Data
Mar. 21, 2025 (JP) 2025-047412

(51) Int. Cl. H10D 30/66; H10D 30/01; H10D 64/00; H10D 64/01

(52) U.S. Cl. CPC H10D 30/668; H10D 30/0297; H10D 64/01; H10D 64/117

(57) ABSTRACT

According to one embodiment, a semiconductor device includes: first, second, and third semiconductor regions stacked in this order, each region containing first, second and the first conductivity type impurities, respectively; a first conductor surrounded by and spaced apart from the first semiconductor region; a first insulating part containing a first insulator, provided in contact with each of a bottom surface and side surfaces in the vicinity of the bottom of the first conductor; a second insulating part including a gap region, provided on a side surface of the first conductor where the first insulator is not provided; a second conductor provided above the first conductor and spaced apart from the first conductor and the second semiconductor region; and a second insulator provided in contact with each of the second semiconductor region and the second conductor.

### CROSS-REFERENCE TO RELATED APPLICATIONS

This application is based upon and claims the benefit of priority from Japanese Patent Application No. 2025-047412, filed Mar. 21, 2025, the entire contents of which are incorporated herein by reference.

### FIELD

Embodiments described herein relate generally to a semiconductor device.

### BACKGROUND

Semiconductor devices such as Metal Oxide Semiconductor Field Effect Transistors (MOSFETs) are used for applications such as power conversion. Such semiconductor devices are required to have a high breakdown voltage and high reliability.

### BRIEF DESCRIPTION OF THE DRAWINGS

FIG. 1 is a plan view illustrating an example of a planar layout of a semiconductor device according to a first embodiment.

FIG. 2 is a plan view illustrating an example of a planar layout of the semiconductor device according to the first embodiment.

FIG. 3 is a sectional view, taken along line III-III of FIG. 2, illustrating an example of a sectional structure of the semiconductor device according to the first embodiment.

FIG. 4 is a sectional view, taken along line IV-IV of FIG. 2, illustrating an example of a sectional structure of the semiconductor device according to the first embodiment.

FIG. 5 is a sectional view illustrating an example of a manufacturing process of the semiconductor device according to the first embodiment.

FIG. 6 is a sectional view illustrating an example of the manufacturing process of the semiconductor device according to the first embodiment.

FIG. 7 is a sectional view illustrating an example of the manufacturing process of the semiconductor device according to the first embodiment.

FIG. 8 is a sectional view illustrating an example of the manufacturing process of the semiconductor device according to the first embodiment.

FIG. 9 is a sectional view illustrating an example of the manufacturing process of the semiconductor device according to the first embodiment.

FIG. 10 is a sectional view illustrating an example of the manufacturing process of the semiconductor device according to the first embodiment.

FIG. 11 is a sectional view illustrating an example of the manufacturing process of the semiconductor device according to the first embodiment.

FIG. 12 is a sectional view illustrating an example of the manufacturing process of the semiconductor device according to the first embodiment.

FIG. 13 is a sectional view illustrating an example of the manufacturing process of the semiconductor device according to the first embodiment.

FIG. 14 is a sectional view illustrating an example of the manufacturing process of the semiconductor device according to the first embodiment.

FIG. 15 is a sectional view illustrating an example of a sectional structure of a semiconductor device according to a second embodiment.

FIG. 16 is a sectional view illustrating an example of a sectional structure of a semiconductor device according to a third embodiment.

FIG. 17 is a sectional view illustrating an example of a sectional structure of a semiconductor device according to a fourth embodiment.

FIG. 18 is a sectional view illustrating an example of a sectional structure of a semiconductor device according to a fifth embodiment.

### DETAILED DESCRIPTION

In general, according to one embodiment, a semiconductor device includes: a first semiconductor region containing a first impurity having a first conductivity type; a second semiconductor region provided on the first semiconductor region and containing a second impurity having a second conductivity type that is different from the first conductivity type; a third semiconductor region provided on the second semiconductor region and containing a third impurity having the first conductivity type; a first conductor surrounded by and spaced apart from the first semiconductor region; a first insulating part provided, between the first semiconductor region and the first conductor, in contact with each of a bottom surface and side surfaces in the vicinity of the bottom of the first conductor, wherein the first insulating part containing a first insulator; a second insulating part provided, between the first semiconductor region and the first conductor, on a side surface of the first conductor where the first insulator is not provided, wherein the second insulating part including a gap region; a second conductor provided above the first conductor and spaced apart from the first conductor and the second semiconductor region; and a second insulator provided, between the second semiconductor region and the second conductor, in contact with each of the second semiconductor region and the second conductor.

Hereinafter, embodiments will be described with reference to the drawings. In the following description, components having substantially the same functions and structures are denoted by the same reference numerals.

In the following description, the expression that a first element is “being connected” to a second element includes a case where the first element is being connected to the second element indirectly through an intermediate element that is always or selectively conductive, or a case where the first element is being connected directly to the second element without the intermediate element.

In the drawings referred to in the following description, an XYZ orthogonal coordinate system is used. The Z direction is also referred to as the “upward direction”, and the opposite direction of the Z direction is also referred to as the “downward direction”. Furthermore, in plan views, hatching is appropriately added to enhance the visibility of the drawing. The hatching added in the plan view is not necessarily related to the material or characteristics of components to which the hatching is added.

### 1. First Embodiment

### 1.1 Planar Structure

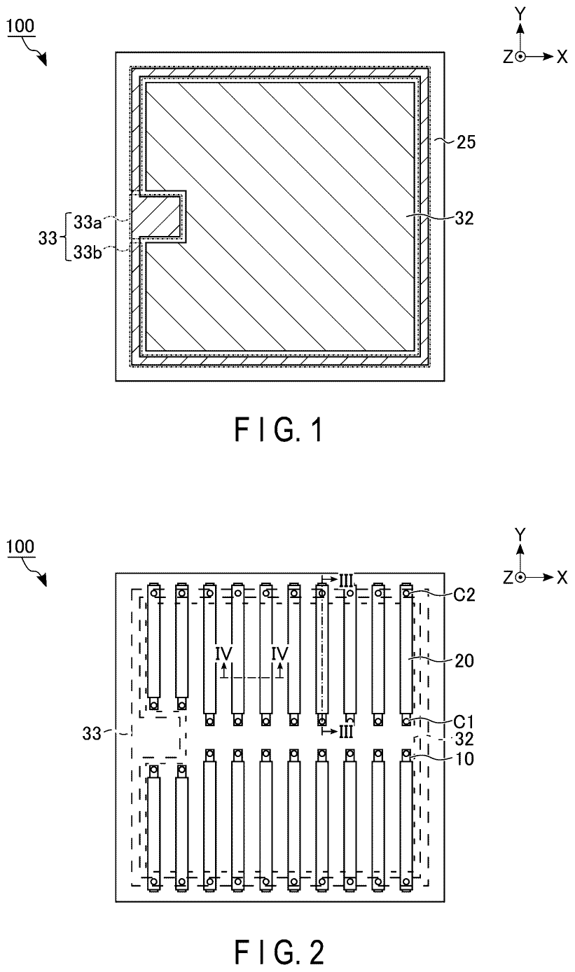

FIG. 1 and FIG. 2 are plan views each illustrating an example of a planar layout of a semiconductor device according to a first embodiment. FIG. 1 illustrates a planar layout of an external appearance of a semiconductor device 100. FIG. 2 illustrates a planar layout of an internal structure of the semiconductor device 100. As illustrated in FIG. 1 and FIG. 2, the semiconductor device 100 includes conductors 10, 20, 32, and 33, an insulator 25, and contacts C1 and C2. In FIG. 2, insulators are omitted in part. Also, in FIG. 2, positions where the conductor 32 and the conductor 33 are provided are shown as regions enclosed by dashed lines.

The semiconductor device 100 is a transistor, for example, a Metal Oxide Semiconductor Field Effect Transistor (MOSFET). The semiconductor device 100 connects or isolates between a drain terminal and a source terminal in accordance with a voltage applied to a gate terminal. In the following, an explanation will be given as to a case where the semiconductor device 100 is an n-channel type MOSFET. As illustrated in FIG. 1, the conductors 32 and 33 are exposed on the upper surface of the semiconductor device 100 and are provided to be spaced apart from each other. The conductor 32 is provided to extend in the XY plane. The conductor 32 serves as an electrode mediating the connection between the semiconductor device 100 and an external device, and functions as a source pad. The conductor 33 includes a first part 33a and a second part 33b. The first part 33a of the conductor 33 is provided to extend in the XY plane. The first part 33a of the conductor 33 serves as an electrode mediating the connection between the semiconductor device 100 and the external device, and functions as a gate pad. The second part 33b of the conductor 33 is provided to enclose the conductor 32 in a square-ring shape in the plan view, and contacts with the first part 33a at ends thereof. The second part 33b of the conductor 33 functions as an interconnect connecting the first part 33a to components provided inside the semiconductor device 100. Portions of the upper surface of the semiconductor device 100, where the conductors 32 and 33 are not provided are covered with the insulator 25. The insulator 25 contains, for example, silicon oxide (SiO).

As illustrated in FIG. 2, each of a plurality of conductors 10 extends in the Y direction and arranged side by side in the X direction. In the example illustrated in FIG. 2, the plurality of conductors 10 are provided in two rows in the Y direction. Each conductor 10 functions as a field plate electrode. The plurality of conductors 10 contain, for example, aluminum (Al), molybdenum (Mo), or polysilicon.

At positions of the ends of the plurality of conductors 10 in the Y direction, where the conductor 32 overlaps in the Z direction, a plurality of contacts C1 are provided. Each contact C1 extends in the Z direction and electrically connects the associated conductor 10 with the conductor 32.

A plurality of conductors 20 are provided above the plurality of conductors 10 and below the conductor 33. Each of the plurality of conductors 20 extends in the Y direction and is arranged side by side in the X direction so as to overlap with the associated conductor 10 in the Z direction. In the example illustrated in FIG. 2, the plurality of conductors 20 are provided in two rows in the Y direction, similar to the plurality of conductors 10. The conductors 10 and 20, which are provided at positions overlapping in the Z direction, are spaced apart from each other and electrically isolated. Each conductor 20 functions as a gate electrode. The plurality of conductors 20 contain, for example, aluminum, molybdenum, or polysilicon.

At positions of the ends of the plurality of conductors 20 in the Y direction, where the conductor 33 overlaps in the Z direction, a plurality of contacts C2 are provided. Each contact C2 extends in the Z direction and electrically connects the associated conductor 20 with the conductor 33.

### 1.2 Sectional Structure

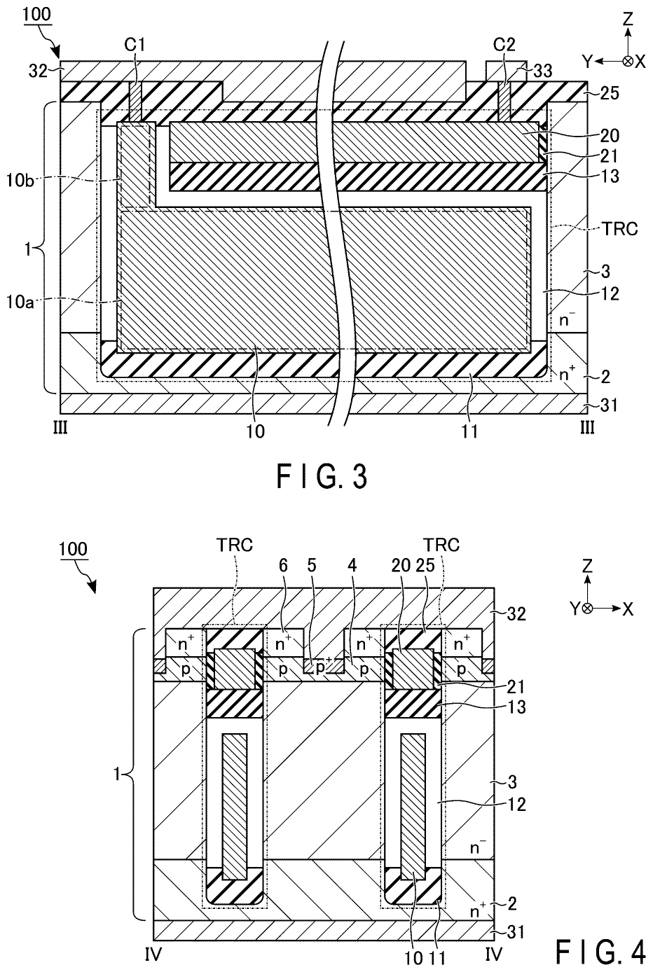

FIG. 3 is a sectional view, taken along line III-III of FIG. 2, illustrating an example of a sectional structure of the semiconductor device according to the first embodiment. FIG. 4 is a sectional view, taken along line IV-IV of FIG. 2, illustrating an example of a sectional structure of the semiconductor device according to the first embodiment. As illustrated in FIG. 3 and FIG. 4, the semiconductor device 100 further includes a semiconductor 1, insulation parts 11, 12, and 13, an insulator 21, and a conductor 31. The semiconductor 1 contains, as a semiconductor material, for example, silicon (Si), silicon carbide (SiC), gallium nitride (GaN), or gallium arsenide (GaAs). In a case where the semiconductor 1 contains silicon as the semiconductor material, as an n-type impurity, for example, arsenic (As), phosphorus (P), or antimony (Sb) may be used. As a p-type impurity, for example, boron (B) or indium (In) may be used.

The conductor 31 is exposed on the lower surface of the semiconductor device 100. The conductor 31 functions as a drain pad. It should be noted that the conductor 31 need not to be exposed entirely on the lower surface of the semiconductor device 100, for example, a part of the conductor 31 may be covered with a not-illustrated insulator.

Above the conductor 31, the semiconductor 1 is provided. The semiconductor 1 is, for example, a silicon substrate. The semiconductor 1 includes semiconductor regions 2, 3, 4, 5, and 6, which are classified based on the conductive type and amount of the impurity contained. More specifically, the semiconductor region 2 is provided at a part where it contacts with the conductor 31. The semiconductor region 2 is a region in which the n-type impurity is doped at a high concentration (n⁺). The concentration of the n-type impurity in the semiconductor region 2 is more than ten times higher compared to the concentration of the n-type impurity in the semiconductor region 3, which will be described later, and is, for example, 1.0×10¹⁷ cm⁻³ or more. The semiconductor region 2 electrically connects with the conductor 31. The semiconductor region 2 functions as the region connected to the drain terminal. Above the semiconductor region 2, the semiconductor region 3 is provided. The semiconductor region 3 is a region in which the n-type impurity is doped at a low concentration (n⁻). The semiconductor region 3 functions as a drift layer. Above the semiconductor region 3, the semiconductor region 4 is provided. The semiconductor region 4 is a region in which the p-type impurity is doped (p). The semiconductor region 4 is provided at a position sandwiched by the plurality of conductors 20 in the X direction. The semiconductor region 4 functions as a region in which a channel (an inversion layer) is formed. A boundary between the semiconductor regions 3 and 4 corresponds to a p-n junction. Above the semiconductor region 4, the semiconductor regions 5 and 6 are selectively provided. The semiconductor region 5 is a region where the p-type impurity is doped at a high concentration (p+). For example, of the semiconductor region 4, a part where the semiconductor region 5 is provided thereon is configured to be thinner in the Z direction compared to a part where the semiconductor region 6 is provided thereon. The semiconductor region 5 is provided at a position sandwiched by the semiconductor region 4 in the X direction. The semiconductor region 5 is not adjacent to a trench structure TRC, which will be described later. The semiconductor region 5 functions as a region to be connected to the gate terminal. The semiconductor region 6 is a region where the n-type impurity is doped at a high concentration (n⁺). The lower surface of the semiconductor region 6 is provided to be upper, for example, than the upper surface of the semiconductor region 5. The semiconductor region 6 is provided so as to sandwich a trench structure TRC, which will be described later, in the X direction. The semiconductor region 6 functions as a region to be connected to the source terminal. It should be noted that the structures of the semiconductor regions 5 and 6 described above are merely examples. As long as the semiconductor region 5 functions as the region that is in contact with the semiconductor region 4 and that connects with the gate terminal, and the semiconductor region 6 functions as the region connected to the source terminal, the structures of the semiconductor regions 5 and 6 may be designed as appropriate.

Note that, the boundary between the semiconductor regions 2 and 3 is a boundary that is conveniently defined based on a concentration gradient of the n-type impurity. Actually, the concentration of the n-type impurity continuously decreases from the semiconductor region 2 to the semiconductor region 3. Therefore, the semiconductor regions 2 and 3 may be regarded as one semiconductor region doped with the n-type impurity. Similarly, the boundary between the semiconductor regions 4 and 5 is a boundary that is conveniently defined based on a concentration gradient of the p-type impurity. Actually, the concentration of the p-type impurity continuously increases from the semiconductor region 4 to the semiconductor region 5. Therefore, the semiconductor regions 4 and 5 may be regarded as one semiconductor region doped with the p-type impurity.

Above a part of the semiconductor 1, the insulator 25 is provided. Above the semiconductor 1 and the insulator 25, the conductors 32 and 33 are provided. As illustrated in FIG. 4, the conductor 32, for example, is in contact, at a position above the semiconductor region 5, with the semiconductor region 5 in the Z direction, and in contact with the semiconductor region 6 in the X direction.

As illustrated in FIG. 3 and FIG. 4, the semiconductor 1 includes a plurality of trench structures TRC. Each of the plurality of trench structures TRC is provided as a groove that extends in the Y direction and that is formed by hollowing out the semiconductor 1 in the Z direction. The bottom of each trench structure TRC reaches the semiconductor region 2 of the semiconductor 1. The conductors 10 and 20 are respectively provided in each of the trench structures TRC.

As illustrated in FIG. 3, in each trench structure TRC, the conductor 10 includes a first part 10a that extends in the Y direction and in the Z direction, and a second part 10b that is provided above the first part 10a and extends in the Z direction. The second part 10b is in contact with the first part 10a at the bottom thereof. The bottom of the first part 10a is provided at a depth corresponding to the semiconductor region 2. The second part 10b is provided in a region in which the conductor 20 is not provided above the second part 10b, and is provided to be aligned with the conductor 20 in the Y direction. The conductor 20 is provided above the first part 10a of the conductor 10 and extends in the Y direction. As illustrated in FIG. 4, the conductor 20 is provided at a depth corresponding to the semiconductor region 4. For example, the upper surface of the second part 10b of the conductor 10 and the upper surface of the conductor 20 are provided at the same height in the Z-direction. The contact C1 contacts with the upper surface of the second portion 10b of the conductor 10. Via the contact C1, the conductor 10 is connected to the conductor 32. The contact C2 contacts with the upper surface of the conductor 20. Via the contact C2, the conductor 20 is connected to the conductor 33. Lengths of the contacts C1 and C2 in the Z direction are approximately the same.

The insulating part 11 is provided in such a manner as to cover the bottom surface and side surfaces in the vicinity of the bottom of the conductor 10. The insulating part 11 contains, for example, an insulator such as silicon oxide. The upper surface of the insulating part 11 is located below the boundary between the semiconductor regions 2 and 3. The insulating part 11 isolates between the conductor 10 and the semiconductor region 2. Furthermore, the insulating part 11 supports the structure of the conductor 10.

Above the insulating part 11, the insulating part 12 is provided in such a manner as to cover the side surfaces of the conductor 10 and the upper surface of the first part 10a of the conductor 10. The insulating part 12 is a gap region. The insulating part 12 is, for example, an air gap. The insulating part 12 contains, for example, air or a gas composed of a substance used in the manufacturing process of the semiconductor device 100. The insulating part 12 isolates between the conductor 10 and the semiconductor regions 2 and 3.

Above the first part of the conductor 10 and above the insulating part 12, the insulating part 13 is provided. The insulating part 13 contains an insulator such as silicon oxide, for example. The insulating part 13 isolates between the conductors 10 and 20. Furthermore, the insulating part 13 supports the structure of the conductor 20.

Above the insulating part 13, the conductor 20 is provided. As illustrated in FIG. 4, the insulator 21 is provided at a position, sandwiched in the X direction, between the conductor 20 and the semiconductor 1, especially semiconductor region 4. The insulator 21 contains, for example, silicon oxide.

Above the conductor 20, the insulator 25 is provided. The insulator 25 covers the upper surface of the conductor 20.

### 1.3 Operation

The semiconductor device 100 electrically connects or isolates between the conductors 31 and 32 depending on the magnitude of voltage applied to the conductor 33. A state in which the conductors 31 and 32 are electrically connected is called the “on state”, and a state in which the conductors 31 and 32 are isolated is called the “off state”. The semiconductor device 100 has a threshold voltage, and when a voltage equal to or greater than the threshold voltage is applied to the conductor 33 which is the gate pad, the semiconductor device 100 enters the on state from the off state. In the following, the operation of the semiconductor device 100 will be explained continuously with reference to FIG. 4.

In a state where a first voltage is applied to the conductor 31 and a second voltage lower than the first voltage is applied to the conductor 32, when a voltage equal to or higher than the threshold voltage is applied to the conductor 33, the channel (the inversion layer) is formed in the semiconductor region 4 adjacent to the conductor 20 via the insulator 21. As electrons move via this channel, a current flows from the conductor 31 toward the conductor 32. Therefore, the semiconductor device 100 enters the on state.

Thereafter, when the voltage applied to the conductor 33 becomes less than the threshold voltage, because the channel is not formed in the semiconductor region 4, the flow of current is blocked. Accordingly, the semiconductor device 100 enters the off state. At the time when the semiconductor device 100 switches from the on state to the off state, a depletion layer extends from the p-n junction at the boundary between the semiconductor regions 3 and 4 toward the semiconductor region 3. At the same time, due to capacitive coupling between the conductor 10 and the semiconductor region 3, a depletion layer extends toward the semiconductor region 3, also from a boundary, which is in contact with the insulating parts 11 to 13, in the semiconductor region 3. As the conductor 10 is provided in the trench structure TRC, depletion of the semiconductor region 3 is promoted, hence the breakdown voltage of the semiconductor device 100 can be improved. In addition, because the concentration of the n-type impurity in the semiconductor region 3 can be increased along with the improvement of the breakdown voltage of the semiconductor device 100, it is possible to reduce the on-resistance of the semiconductor device 100 in the on state.

### 1.4 Manufacturing Process

FIGS. 5, 6, 7, 8, 9, 10, 11, 12, 13, and 14 are sectional views each illustrating an example of the manufacturing process of the semiconductor device according to the first embodiment. FIGS. 5, 6, 7, 8, 9, 10, 11, 12, 13, and 14 correspond to the sectional region illustrated in FIG. 4. Hereinafter, the manufacturing process of the semiconductor device 100 will be explained with reference to FIGS. 5, 6, 7, 8, 9, 10, 11, 12, 13, and 14 as appropriate.

First, the semiconductor 1 including the semiconductor regions 2 and 3 is formed. For example, by growing an epitaxial layer corresponding to the semiconductor region 3 on the n⁺-semiconductor substrate, which corresponds to the semiconductor region 2 and which is doped with the n-type impurity at a high concentration, the semiconductor 1 is formed. Thereafter, a trench T corresponding to the trench structure TRC is formed. More specifically, a mask having an opening in the region corresponding to the trench structure TRC is formed. Subsequently, by performing Reactive Ion Etching (RIE) or the like using this mask, the trench T is formed. The bottom of the trench T reaches the semiconductor region 2. Thereafter, for example, by performing thermal annealing and oxidizing the surface of the semiconductor 1, the insulating part 11 is formed along the inner wall of the trench T and along the upper surface of the semiconductor 1, as illustrated in FIG. 5. The insulator contained in the insulating part 11, which was formed by subjecting the semiconductor 1 to the thermal oxidation, contains silicon oxide. It should be noted that the method for forming the insulating part 11 is not limited to the method described above. For example, the insulator may be deposited along the inner wall of the trench T.

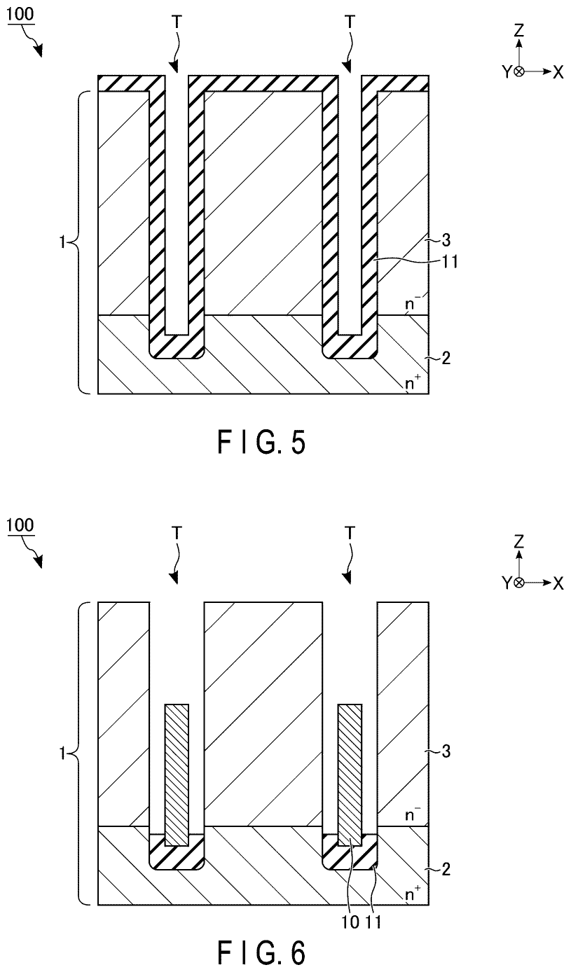

Next, the conductor 10 is formed inside the trench T. The lower end of the conductor 10 is provided inside the semiconductor region 2. After embedding the conductor 10 inside the trench T, by selectively etching back the upper surface of the conductor 10, the conductor 10 having the first part 10a and the second part 10b is formed. Thereafter, as illustrated in FIG. 6, the etch-back process is selectively performed on the upper part of the insulating part 11 on the sidewall of the trench T to partially remove the insulating part 11. At this time, the etch-back process is performed so that the insulating part 11 remains on the sides in the vicinity of the bottom of the conductor 10. By this etch-back process, the upper surface of the insulating part 11 is provided inside the semiconductor region 2.

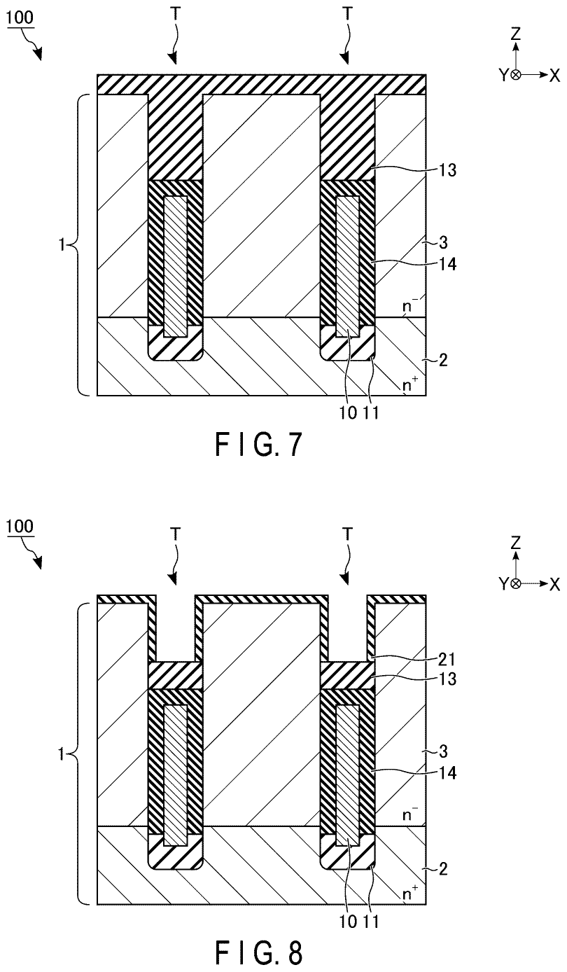

Next, as illustrated in FIG. 7, a sacrificial member 14 and the insulating part 13 are embedded in this order into the trench T. The sacrificial member 14 is provided in the part corresponding to the insulating part 12. The sacrificial member 14 contains a material that is capable of selectively etching the semiconductor 1, and the insulating parts 11 and 13 as well. The sacrificial member 14 contains, for example, silicon nitride (SiN). The sacrificial member 14 is provided in such a manner as to fill out the trench T and is partially removed by the etch-back process. Subsequently, the insulating part 13 is embedded above the sacrificial member 14.

Next, after the insulating part 13 is removed by the etch-back process, annealing is performed again on the semiconductor 1. As illustrated in FIG. 8, the insulator 21 is formed along the inner wall of the trench T and the upper surface of the semiconductor 1. The insulator 21, which was formed by thermal oxidation of the semiconductor 1, contains silicon oxide. It should be noted that the method for forming the insulator 21 is not limited to the method described above. For example, the insulator may be deposited along the inner wall of the trench T.

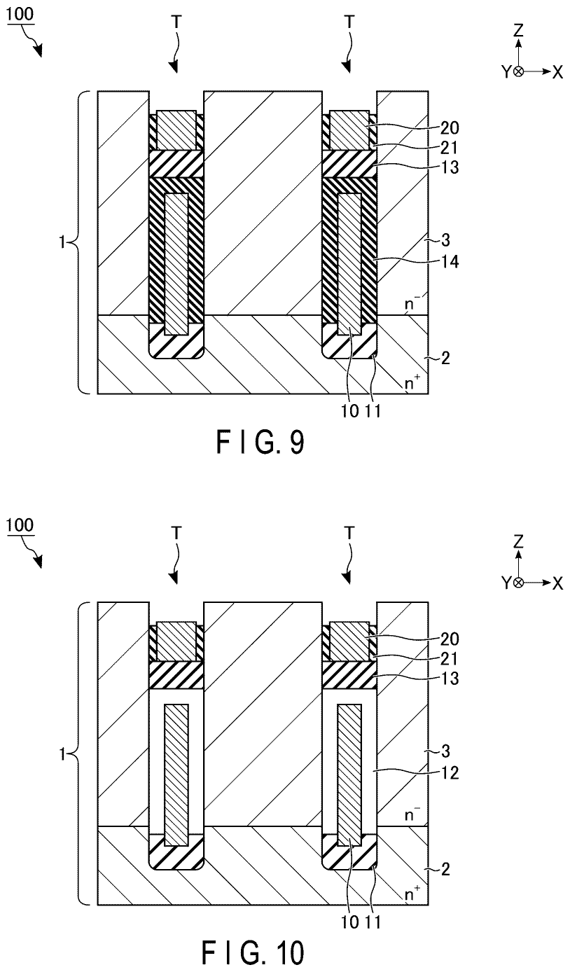

Next, the conductor 20 is formed inside the trench T. The upper surface of the conductor 20 is provided in such a manner as to, for example, align with the height of the upper surface of the second part 10b of the conductor 10. Thereafter, as illustrated in FIG. 9, the etch-back process is selectively performed to the upper part of the insulator 21 on the sidewall of the trench T to partially remove the insulator 21. At this time, the insulator 21 provided between the conductor 20 and the semiconductor 1 remains without being removed.

Next, as illustrated in FIG. 10, the sacrificial member 14 is selectively removed by wet etching via the trench T. More specifically, the sacrificial member 14 is removed via the part, in the vicinity of the region where the second part 10b of the conductor 10 is provided, where the sacrificial member 14 is exposed to the upper surface inside the trench T. For example, in a case where the sacrificial member 14 contains silicon nitride and the insulating parts 11 and 13 contain silicon oxide, by wet etching using phosphoric acid, the sacrificial member 14 can be selectively removed. The region where the sacrificial member 14 was removed becomes a gap region, and the insulating part 12 is formed.

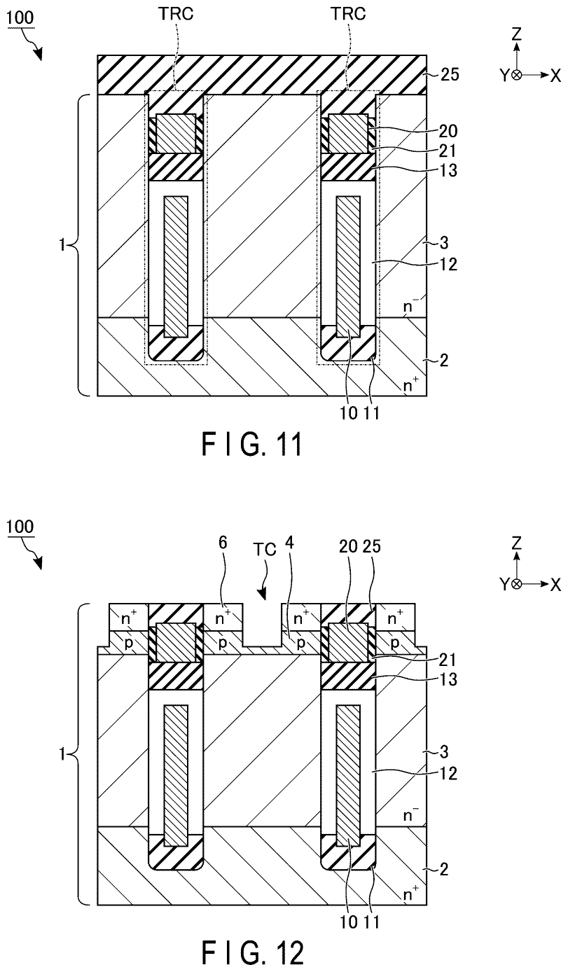

Next, as illustrated in FIG. 11, the insulator 25 is embedded in the trench T. With this, the trench structure TRC is completed. At this time, the part, in the vicinity of the region where the second part 10b of the conductor 10 is provided, where the insulating part 12 is exposed to the upper surface inside the trench T, is filled with the insulator 25, and the gap region included in the insulating part 12 is sealed. Subsequently, the insulator 25 is partially removed by the etch-back process.

Next, in the region sandwiched by the plurality of trench structures TRC in the X direction, the p-type impurity and the n-type impurity are sequentially doped into the exposed semiconductor 1 to form the semiconductor region 4 and the semiconductor region 6. The doping of the p-type impurity and the n-type impurity is performed, for example, by ion implantation. Thereafter, as illustrated in FIG. 12, the trench TC is provided in the part where the semiconductor regions 4 and 6 of the semiconductor 1 are formed. The trench TC passes through the semiconductor region 6 of the semiconductor 1 in the Z direction, and the bottom thereof reaches the semiconductor region 4. Thereafter, although not shown, the structure corresponding to the contacts C1 and C2 is formed.

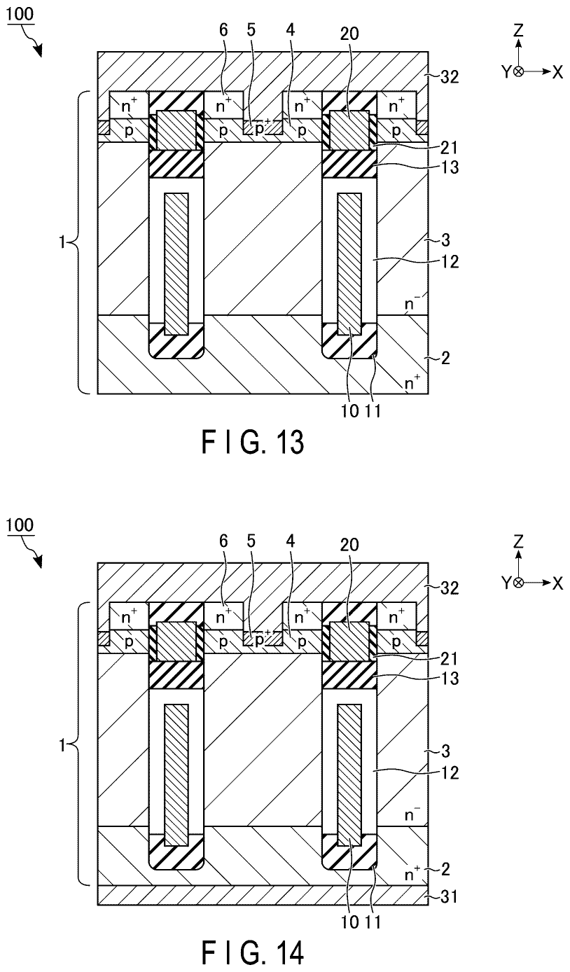

Next, the p-type impurity is doped into the semiconductor 1 via the trench TC to form the semiconductor region 5. Subsequently, as illustrated in FIG. 13, the conductor 32 is formed in such a manner as to fill the trench TC. The conductor 32 is connected to the conductor 10 via the contact C1. Thereafter, although not shown, the conductor 33 is formed. The conductor 33 is connected to the conductor 20 via the contact C2.

Finally, as illustrated in FIG. 14, the lower part of the semiconductor region 2 is removed by, for example, back grinding or Chemical Mechanical Polishing (CMP), and then the conductor 31 is provided, at the bottom of the semiconductor device 100, in contact with the semiconductor region 2. Although not shown, an insulator may further be provided to cover a part of the lower surface of the conductor 31.

By the above-described steps, the semiconductor device 100 is formed. It should be noted that the manufacturing process described above is merely one example and is not limited thereto. For example, other processes may be inserted between the manufacturing steps, and some steps may be omitted or combined. Furthermore, each manufacturing step may be interchanged within a possible extent.

### 1.5 Effect

The semiconductor device 100 according to the first embodiment has high breakdown voltage and high reliability. Hereinafter, an explanation will be given as to this effect derived from the semiconductor device 100.

At the time when the semiconductor device 100 switches from the on state to the off state, the depletion layer extends toward the semiconductor region 3. At this time, an electric field strength at the boundary between the semiconductor region 3 and the insulating parts 11 and 12 surrounding the conductor 10 increases. In a case where the thicknesses in the X direction of the insulating parts 11 and 12 surrounding the conductor 10 (hereinafter referred to as the film thickness) are too thin, the electric field strength at the boundary exceeds a critical electric field of the semiconductor region 3, and breakdown occurs, thus there is a possibility that the breakdown voltage of the semiconductor device 100 may decrease. On the other hand, in a case where the film thicknesses of the insulating parts 11 and 12 surrounding the conductor 10 are too thick, since the capacitive coupling between the conductor 10 and the semiconductor region 3 is small, extension of the depletion layer into the semiconductor region 3 is suppressed, hence there is a possibility that the breakdown voltage of the semiconductor device 100 may decrease. Accordingly, it is desirable to design the film thicknesses of the insulating parts 11 and 12 to be an optimal thickness that is neither too thick nor too thin.

The semiconductor device 100 according to the first embodiment is provided with the insulating part 12 between the conductor 10 and the semiconductor region 3. The insulating part 12 contains air, and a dielectric constant in the air is lower than a dielectric constant of silicon oxide, silicon nitride or the like that are generally used as an insulator. Therefore, by forming the insulating part 12, compared to the structure in which silicon oxide, silicon nitride or the like is provided, the thickness of the layer in the X direction can be made thin, while suppressing the occurrence of breakdown. Furthermore, by reducing the thickness of the insulating part 12, the number of the conductors 20 per unit area can be increased, hence it is possible to decrease the on-resistance of the semiconductor device 100.

On the other hand, by providing the gap region as the insulating part, the structure may become unstable. For example, in a case where all the insulating parts surrounding the conductor 10 were formed by the gap region, because the structure for supporting the conductor 10 from below cannot be provided, there is a possibility that, due to shocks or the like, the conductor 10 may detach from the insulator 25 and fall off. As such, due to change in the structure of the semiconductor device 100, the reliability of the semiconductor 100 may decrease. Furthermore, in the manufacturing process of the trench structure TRC in which all the insulating parts are formed of the gap region, similar to the first embodiment, the trench structure TRC is formed by removing the sacrificial member corresponding to the gap region by etching or the like. However, in a case where the sacrificial member was not completely removed in the etching process and partially remained at the bottom of the trench structure, since the electric field concentrates at the part where the sacrificial member remains and breakdown occurs, there is a possibility that the breakdown voltage of the semiconductor device 100 may decrease.

The semiconductor device 100 according to the first embodiment is provided, at the bottom of the trench structure TRC, with the insulating part 11 so as to cover the bottom surface and the sides in the vicinity of the bottom of the conductor 10. With this configuration, the structure of the conductor 10 is supported and the position of the conductor 10 is fixed. Therefore, since the mechanical strength of the trench structure TRC increases, and the resistance to impacts and the like is improved, the reliability of the semiconductor device 100 is improved.

Furthermore, the semiconductor device 100 according to the first embodiment has the structure in which the bottom of the trench structure TRC reaches the semiconductor region 2 in which the concentration of the n-type impurity is high, and the insulating part 11 is provided inside the semiconductor region 2. Since the concentration of the n-type impurity is high in the semiconductor region 2, when the semiconductor device 100 switches from the on state to the off state, the depletion layer is less likely to extend into the semiconductor region 2. For this reason, in the part, which is provided in the vicinity of the semiconductor region 2, of the insulating part surrounding the conductor 10, an electric field generated along with extension of the depletion layer is small, compared to that in the part provided in the semiconductor region 3. Accordingly, even in a case where the insulating part 11 provided in the semiconductor region 2 contains an insulator with a dielectric constant higher than that of air, for example, silicon oxide, concentration of the electric field in the insulating part 11 is less likely to occur, and occurrence of the breakdown is suppressed, hence the thickness of the insulating part 11 can be made thin. Accordingly, the insulating part 11 can be provided with a film thickness similar to that of the insulating part 12 provided in the semiconductor region 3. With this configuration, it is possible to reduce the overall thickness of the insulating part while maintaining sufficiently high breakdown voltage. Furthermore, in the manufacturing process of the semiconductor device 100, even in a case where the sacrificial material 14 has partially remained at the bottom of the trench structure TRC in the etching of the sacrificial material 14, since the concentration of the electric field in the part where the sacrificial material 14 has partially remained is less likely to occur, an influence on the decrease in the breakdown voltage of the semiconductor device 100 is small. Therefore, the stability of the manufacturing process of the trench structure TRC is improved.

In addition, the semiconductor device 100 according to the first embodiment has the structure in which the bottom of the trench structure TRC reaches the semiconductor region 2 in which the concentration of the n-type impurity is high. Because the higher the concentration of the n-type impurity, the shorter the lifetime of the carrier in the semiconductor region 2 becomes, it is possible to reduce a reverse recovery charge in the reverse recovery operation of the body diode structurally possessed in the semiconductor device 100. For this reason, the power consumption in the circuit in which the body diode of the semiconductor device 100 operates can be reduced.

### 2. Second Embodiment

Next, a semiconductor device according to a second embodiment will be described. In the following, explanations on a structure and a manufacturing process that are equivalent to those in the first embodiment will be omitted, and an explanation will be given mainly as to the configuration that differs from that of the first embodiment.

### 2.1 Structure

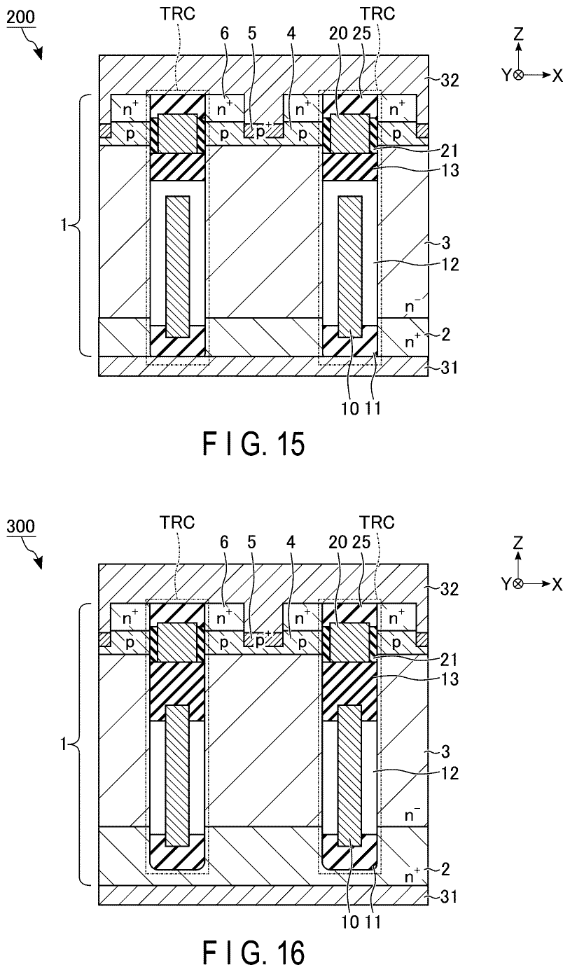

FIG. 15 is a sectional view illustrating an example of a sectional structure of the semiconductor device according to the second embodiment. FIG. 15 corresponds to the section illustrated in FIG. 4 of the first embodiment. As illustrated in FIG. 15, in a semiconductor device 200 according to the second embodiment, the bottom of the trench structure TRC is in contact with the conductor 31. In other words, the conductor 31 is provided to be in contact with the bottom of the semiconductor region 2 and the bottom of the insulating part 11 in the trench structure TRC.

### 2.2 Manufacturing Process

An explanation will be given as to the manufacturing process of the semiconductor device 200 according to the second embodiment. The semiconductor device 200 according to the second embodiment is formed by the similar steps up to the step illustrated in FIG. 13 in the manufacturing process of the semiconductor device 100 according to the first embodiment. Subsequently, before providing the conductor 31, the lower surface of the semiconductor region 2 is partly removed using, for example, CMP or the like, thereby exposing the insulating part 11 in the trench structure TRC. At this time, as long as the insulating part 12 in the trench structure TRC does not expose, the insulating portion 11 may also be partly removed simultaneously with the removal of the semiconductor region 2. Thereafter, the conductor 31 is provided so as to be in contact with the semiconductor region 2 and the insulating portion 11. It should be noted that, although not shown, an insulator covering a part of the lower surface of the conductor 31 may further be provided.

### 2.3 Effect

In the semiconductor device 200 according to the second embodiment, a distance between the conductor 31 functioning as the drain pad and the conductor 32 functioning as the source pad is shortened compared to that of the semiconductor device 100. Therefore, the on-resistance of the semiconductor device 200 can be reduced. Furthermore, since the trench structure TRC has a structure in which the conductor 10 is fixed by the insulating part 11, the mechanical strength is increased. Therefore, in the step of removing the lower surface of the semiconductor region 2 in the manufacturing process of the semiconductor device 200, destruction of the trench structure TRC is suppressed.

### 3. Third Embodiment

Next, a semiconductor device according to a third embodiment will be described. In the following, explanations on a structure and a manufacturing process that are equivalent to those in the first embodiment will be omitted, and an explanation will be given mainly as to the configuration that differs from that of the first embodiment.

### 3.1 Structure

FIG. 16 is a sectional view illustrating an example of a sectional structure of the semiconductor device according to the third embodiment. FIG. 16 corresponds to the section illustrated in FIG. 4 of the first embodiment. As illustrated in FIG. 16, a semiconductor device 300 according to the third embodiment is provided with the insulating part 13 in the trench structure TRC so as to cover the upper surface and the side surfaces in the vicinity of the upper part of the conductor 10.

### 3.2 Manufacturing Process

An explanation will be given as to the manufacturing process of the semiconductor device 300 according to the third embodiment. The semiconductor device 300 according to the third embodiment is formed by the similar steps up to the step illustrated in FIG. 6 in the manufacturing process of the semiconductor device 100 according to the first embodiment. Subsequently, the sacrificial material 14 is embedded, and etching is performed so that the upper surface and the side surfaces in the vicinity of the upper part of the conductor 10 expose. Thereafter, the insulating part 13 is embedded in the etched parts. The subsequent steps are similar to those in the manufacturing process of the semiconductor device 100 according to the first embodiment.

### 3.3 Effect

The semiconductor device 300 according to the third embodiment is provided with the insulating parts 12 and 13 between the conductor 10 and the semiconductor region 3. A dielectric constant of the insulator contained in the insulating part 13 is higher than a dielectric constant of the air contained in the insulating part 12. In other words, when the insulating parts 12 and 13 are regarded as one insulating part, the thickness of the insulating part is common, the dielectric constant at the upper part is high, and the dielectric constant at the lower part is low. With such a structure, when capacitive coupling occurs between the conductor 10 and the semiconductor region 3, because the capacitive coupling of the upper part becomes strong, compared to a case where the dielectric constant is uniformly low, it is possible to increase the electric field strength. Therefore, it is possible to enhance the breakdown voltage of the semiconductor device 300.

Furthermore, by providing the insulating part 13 in such a manner as to cover the upper surface and the side surfaces in the vicinity of the upper part of the conductor 10, the upper position of the conductor 10 is fixed. With this configuration, within the trench structure TRC, the position of the conductor 10 is fixed in both of the downward direction and the upward direction by the insulating parts 11 and 13. Therefore, the mechanical strength of the trench structure TRC increases, and the resistance to impacts and the like is improved, hence the reliability of the semiconductor device 300 is improved.

### 4. Fourth Embodiment

Next, a semiconductor device according to a fourth embodiment will be described. In the following, explanations on a structure and a manufacturing process that are equivalent to those in the first embodiment will be omitted, and an explanation will be given mainly as to the configuration that differs from that of the first embodiment.

### 4.1 Structure

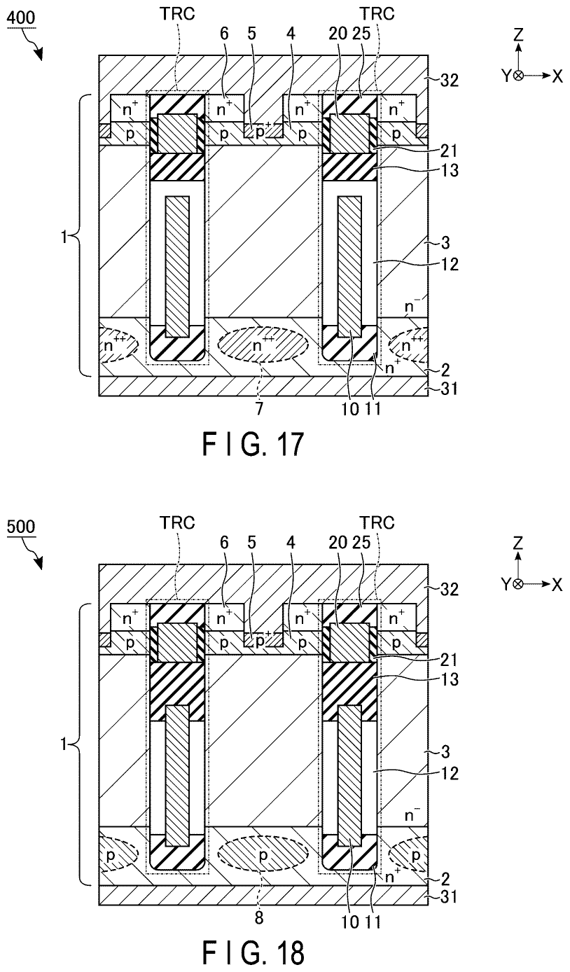

FIG. 17 is a sectional view illustrating an example of a sectional structure of the semiconductor device according to the fourth embodiment. FIG. 17 corresponds to the section illustrated in FIG. 4 of the first embodiment. As illustrated in FIG. 17, a semiconductor device 400 according to the fourth embodiment includes semiconductor regions 7 inside the semiconductor region 2. The semiconductor regions 7 are regions in which the n-type impurity is doped at a higher concentration (n⁺⁺) than in the semiconductor region 2. The semiconductor regions 7 are provided locally inside the semiconductor region 2 as appropriate, and for example, provided so as to surround the insulating part 11 of the trench structure TRC.

### 4.2 Manufacturing Process

An explanation will be given as to the manufacturing process of the semiconductor device 400 according to the fourth embodiment. In the semiconductor device 400 according to the fourth embodiment, after forming a trench T corresponding to the trench structure TRC, the n-type impurity is injected into the semiconductor 1, thereby forming the semiconductor regions 7. For example, the n-type impurity is injected via both the trench and a mesa adjacent to the trench from a front surface of the semiconductor 1. The portion of the n-type impurity injected via the trench penetrates deep into the lower part of the semiconductor region 2, and is subsequently removed during a process such as back grinding or CMP. As a result, only the semiconductor regions 7 in the mesa remain. The subsequent steps are similar to those in the manufacturing process of the semiconductor device 100 according to the first embodiment.

### 4.3 Effect

The semiconductor device 400 according to the fourth embodiment has, inside the semiconductor region 2, the semiconductor regions 7, which have a higher concentration of the n-type impurity than the surroundings. By virtue of this structure, at the time when the semiconductor device 400 switches from the on state to the off state, generation of the electric field due to the extension of the depletion layer is further suppressed around the semiconductor regions 7. For this reason, concentration of the electric field in the insulating part (e.g., insulating part 11) around the semiconductor regions 7 is further suppressed, and the occurrence of breakdown is suppressed. Therefore, the reliability of the semiconductor device 400 can be improved.

### 5. Fifth Embodiment

Next, a semiconductor device according to a fifth embodiment will be described. In the following, explanations on a structure and a manufacturing process that are equivalent to those in the first embodiment will be omitted, and an explanation will be given mainly as to the configuration that differs from that of the first embodiment.

### 5.1 Structure

FIG. 18 is a sectional view illustrating an example of a sectional structure of the semiconductor device according to the fifth embodiment. FIG. 18 corresponds to the section illustrated in FIG. 4 of the first embodiment. As illustrated in FIG. 18, a semiconductor device 500 according to the fifth embodiment includes semiconductor regions 8 inside the semiconductor region 2. The semiconductor regions 8 are regions in which the p-type impurity is doped (p). The boundary between the semiconductor regions 2 and 8 corresponds to a p-n junction. The semiconductor regions 8 are provided locally within the semiconductor region 2, as appropriate, and for example, provided to surround the insulating part 11 of the trench structure TRC.

### 5.2 Manufacturing Process

An explanation will be given as to the manufacturing process of the semiconductor device 500 according to the fifth embodiment. In the semiconductor device 500 according to the fifth embodiment, after forming a trench T corresponding to the trench structure TRC the p-type impurity is injected into the semiconductor 1, thereby forming the semiconductor regions 7. For example, the p-type impurity is injected via both the trench and a mesa adjacent to the trench from a front surface of the semiconductor 1. The portion of the p-type impurity injected via the trench penetrates deep into the lower part of the semiconductor region 2, and is subsequently removed during a process such as back grinding or CMP. As a result, only the semiconductor regions 7 in the mesa remain. The subsequent steps are similar to those in the manufacturing process of the semiconductor device 100 according to the first embodiment.

### 5.3 Effect

The semiconductor device 500 according to the fifth embodiment has the semiconductor regions 8, which contain the p-type impurity, inside the semiconductor region 2. By virtue of this structure, because an electric field is generated also at a newly formed p-n junction at the boundary between the semiconductor regions 2 and 8, and the depletion layer extends, concentration of the electric field in the insulating part (e.g., the insulating part 11) around the semiconductor regions 8 is suppressed, and the occurrence of breakdown is suppressed. Therefore, the reliability of the semiconductor device 500 can be improved.

### 6. Other

In the first to fifth embodiments, explanations have been given as to the n-channel MOSFET in which a channel is formed in the semiconductor region 3 doped with the n-type impurity. However, a similar structure can also be applied to a p-channel MOSFET. In this case, the conductive type of the impurity doped into each semiconductor region is opposite to the conductive type of the impurity doped in the first to fifth embodiments. That is, the p-type impurity is doped into regions corresponding to the semiconductor regions 2, 3, 6, and 7, while the n-type impurity is doped into regions corresponding to the semiconductor regions 4, 5, and 8.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first semiconductor region containing a first impurity having a first conductivity type;
a second semiconductor region provided on the first semiconductor region and containing a second impurity having a second conductivity type that is different from the first conductivity type;
a third semiconductor region provided on the second semiconductor region and containing a third impurity having the first conductivity type;
a first conductor surrounded by and spaced apart from the first semiconductor region;
a first insulating part provided, between the first semiconductor region and the first conductor, in contact with each of a bottom surface and side surfaces in the vicinity of the bottom of the first conductor, wherein the first insulating part containing a first insulator;
a second insulating part provided, between the first semiconductor region and the first conductor, on a side surface of the first conductor where the first insulator is not provided, wherein the second insulating part including a gap region;
a second conductor provided above the first conductor and spaced apart from the first conductor and the second semiconductor region; and
a second insulator provided, between the second semiconductor region and the second conductor, in contact with each of the second semiconductor region and the second conductor.

2. The device according to claim 1, wherein:
the first semiconductor region includes a first part in which the first impurity is contained at a first concentration, and a second part, provided on the first part, in which the first impurity is contained at a second concentration lower than the first concentration, and
the bottom surface of the first conductor is located below a boundary between the first part and the second part of the first semiconductor region.

3. The device according to claim 2, wherein the first concentration of the first impurity in the first part of the first semiconductor region is not less than 1.0×10¹⁷ cm⁻³.

4. The semiconductor device according to claim 2, wherein:
the first insulating part is provided, between the first part of the first semiconductor region and the first conductor, in contact with each of the first part of the first semiconductor region and the first conductor, and
the second insulating part is provided between the second part of the first semiconductor region and the first conductor.

5. The device according to claim 4, wherein an upper end of the first insulating part is located below the boundary between the first part and the second part of the first semiconductor region.

6. The device according to claim 4, wherein:
film thicknesses of the first insulating part and the second insulating part in a direction from the first conductor toward the first semiconductor region are substantially equal to each other, and
a dielectric constant of the second insulating part is lower than a dielectric constant of the first insulating part.

7. The device according to claim 1, further comprising a third insulating part provided in contact with the second conductor, the third insulating part being located above the first conductor and the second insulating part and below the second conductor,
wherein the third insulating part contains a third insulator, is in contact with the first conductor to cover an upper surface of the first conductor, and is provided, between the first semiconductor region and the first conductor, in contact with each of the first semiconductor region and the first conductor at side surfaces in the vicinity of the upper part of the first conductor.

8. The device according to claim 7, wherein:
film thicknesses of the second insulating part and the third insulating part in a direction from the first conductor toward the first semiconductor region are substantially equal to each other, and
a dielectric constant of the third insulating part is higher than a dielectric constant of the second insulating part.

9. The device according to claim 1, further comprising a third conductor provided in contact with the first semiconductor region and the first insulating part, under the first semiconductor region and the first insulating part.

10. The device according to claim 2, wherein a fourth semiconductor region is locally included inside the first part of the first semiconductor region, the fourth semiconductor region containing the first impurity at a third concentration higher than the first concentration.

11. The device according to claim 2, wherein a fifth semiconductor region is locally included inside the first part of the first semiconductor region, the fifth semiconductor region containing the second impurity.

12. A semiconductor device comprising:
a first semiconductor region including a first part in which a first impurity of a first conductivity type is contained at a first concentration, and a second part provided on the first part, in which the first impurity is contained at a second concentration lower than the first concentration;
a second semiconductor region provided on the first semiconductor region and containing a second impurity having a second conductivity type that is different from the first conductivity type;
a third semiconductor region provided on the second semiconductor region and containing a third impurity having the first conductivity type;
a first conductor surrounded by and spaced apart from the first semiconductor region;
a first insulating part provided, on a bottom surface of the first conductor, between the first part of the first semiconductor region and the first conductor, in contact with each of the first part of the first semiconductor region and the first conductor, wherein the first insulating part containing a first insulator;
a second insulating part provided, on a side surface of the first conductor, between the second part of the first semiconductor region and the first conductor, wherein the second insulating part including a gap region;
a second conductor provided above the first conductor and spaced apart from the first conductor and the second semiconductor region; and
a second insulator provided between the second semiconductor region and the second conductor, in contact with the second semiconductor region and the second conductor.

13. The device according to claim 12, wherein the first concentration of the first impurity in the first part of the first semiconductor region is not less than 1.0×10¹⁷ cm⁻³.

14. The device according to claim 12, wherein an upper end of the first insulating part is located below a boundary between the first part and the second part of the first semiconductor region.

15. The device according to claim 12, wherein:
film thicknesses of the first insulating part and the second insulating part in a direction from the first conductor toward the first semiconductor region are substantially equal to each other, and
a dielectric constant of the second insulating part is lower than a dielectric constant of the first insulating part.

16. The device according to claim 12, further comprising a third insulating part provided above the first conductor and the second insulating part and below the second conductor, in contact with the second conductor,
wherein the third insulating part contains a third insulator, is in contact with the first conductor to cover an upper surface of the first conductor, and is provided, between the first semiconductor region and the first conductor, in contact with each of the first semiconductor region and the first conductor at side surfaces in the vicinity of the upper part of the first conductor.

17. The device according to claim 16, wherein
film thicknesses of the second insulating part and the third insulating part in a direction from the first conductor toward the first semiconductor region are substantially equal to each other, and
a dielectric constant of the third insulating part is higher than a dielectric constant of the second insulating part.

18. The device according to claim 12, further comprising a third conductor provided in contact with the first semiconductor region and the first insulating part, under the first semiconductor region and the first insulating part.

19. The device according to claim 12, wherein a fourth semiconductor region is locally included inside the first part of the first semiconductor region, the fourth semiconductor region containing the first impurity at a third concentration higher than the first concentration.

20. The device according to claim 12, wherein a fifth semiconductor region is locally included inside the first part of the first semiconductor region, the fifth semiconductor region containing the second impurity.
